(19) United States
(12) Patent Application Publication
(10) Pub. No.: US 2012/0050969 A1
(43) Pub. Date: Mar. 1, 2012

(54) ELECTRONIC DEVICE WITH A TOUCH SCREEN, COMPRISING A STAND WITH AT LEAST THREE POSITIONS OF USE

(75) Inventor: Henri CROHAS, Verrieres-Le-Buisson (FR)

(73) Assignee: ARCHOS, Igny (FR)

(21) Appl. No.: 13/221,998

(22) Filed: Aug. 31, 2011

(30) Foreign Application Priority Data
Aug. 31, 2010 (FR) 10 56910

(51) Int. Cl. H05K 7/00

(52) U.S. Cl. 361/679.01

(57) ABSTRACT

An electronic device with a touch screen includes a casing on which the touch screen is mounted, at least one stand pivoting with respect to the casing between a retracted position in the casing of the device, and a maximum deployed position, corresponding to a so-called “reclining” configuration of the device, in which the angle between the outer visible face of the touch screen and the vertical ranges between 50° and 85° when a base of the device and the stand are supported on a horizontal plane, the stand moreover being able to be arranged in at least one intermediate deployed position, corresponding to a so-called “upright” configuration of the device, in which the angle between the outer visible face of the touch screen and the vertical ranges between 5° and 45° when the base of the device and the stand are supported on the horizontal plane.

The invention relates to the field of portable electronic devices equipped with a touch screen, and in particular devices of this type constituted by a one-piece body or capable of being presented in a one-piece compact configuration.

Electronic devices with touch screens now have the advantage of incorporating computing power which makes them capable of running sophisticated interactive applications such as internet navigation, email management, etc. Certain models are even capable of running conventional office computer applications such as word processing, spreadsheet, and presentation management software. Moreover, these devices are also capable of decoding and displaying digital video content.

In terms of ergonomics, it is apparent that there are two main modes of use of these devices depending on the usages and/or type of interaction means used. These two main modes of use being associated with a given orientation of the screen.

The first of the two main modes of use, the so-called “upright” mode requires the screen to be tilted close to the vertical. This tilt corresponds to usages which are not interactive or only to a minor extent, such as displaying a video, slide show or presentation. It can also be used for applications which are highly interactive but in which the user's actions utilize peripherals or means external to the device, such as a keyboard or an external mouse. Overall, in this first mode of use, the device is not used, or only very little used, as a direct means of command or entry via its touch screen.

The second of the two main modes of use, the so-called “reclining” mode requires the screen to be tilted close to the horizontal. This tilt corresponds to interactive usages involving the use of the touch screen as a means of action for the user. This second mode of use is particularly suitable for applications requiring commands and/or the entry of characters by means of a virtual keyboard which is displayed on the touch screen, in addition to its standard display function. It is noted that the “reclining” position must be distinct from the horizontal or “flat” position, a slight tilt with respect to the horizontal being preferred for ergonomic reasons: better accessibility for the fingers and greater ease of reading when the screen is slightly tilted, for example between 5° and 40° with respect to the horizontal.

The problem of adapting the orientation of the screen and the support of the devices of the prior art in the context of the above two main modes of use has not been entirely solved. Devices are known forming a support, pedestal or base on which the electronic device is placed to be used “upright” or “reclining”. These devices which are separate from the electronic device are expensive, bulky and likely to be lost or not available when needed. Devices provided with a stand which can be deployed are also known, the possible uses and the stability of which are extremely limited. Moreover the known solutions have too high a utilization cost and/or occupy too great a volume inside the casing of the device and/or have too great a space requirement in the thickness direction for a mass-produced portable device.

To this end, a subject of the invention is an electronic device with a touch screen, in particular of the one-piece type, or capable of adopting a general one-piece form, comprising a casing on which the touch screen is mounted, the device having a general flattened shape delimited by two substantially parallel and rectangular opposite faces, one of which substantially incorporates the outer visible face of the touch screen, characterized in that it comprises at least one stand pivoting with respect to the casing between a retracted position in the casing of the device, and a maximum deployed position, corresponding to a so-called “reclining” configuration of the device, in which the angle between the outer visible face of the touch screen and the vertical is comprised between 50° and 85° when a base of the device and the stand are supported on a horizontal plane, the stand moreover being able to be arranged in at least one intermediate deployed position, corresponding to a so-called “upright” configuration of the device, in which the angle between the outer visible face of the touch screen and the vertical is comprised between 5° and 45° when the base (10) of the device and the stand (7-9) are supported on the horizontal plane (H).

The axis of rotation of the stand is positioned so that the projection of the device's centre of gravity on the horizontal plane is comprised inside the surface delimited by the support points of the base of the device and those of the at least one stand in its position of extreme adjustment of the “upright” position. The combination of the different forces leads to the formation of a weak torque on the stand. This weak torque on the stand in the “upright” position is easily overcome by frictional forces, in particular by those which are exerted at the level of the articulation of the stand and between the points of contact between its end and the horizontal plane on which the device is placed.

Thus, the stand can adopt at least three positions of use, including a folded-away or retracted position and at least two distinct deployed positions. The stand constitutes the same single means of retention of the device irrespective of the chosen “upright or “reclining” position of the device. This means is of a simple and inexpensive design, perfectly integrated into the casing of the device in its retracted position, therefore having a minimal space requirement; it is permanently incorporated into the device, which means that it is always available.

According to yet other advantageous characteristics of the invention, the angle formed between the rectilinear direction of the stand and the outer visible face of the touch screen is comprised between 100° and 175° when the stand is in the maximum deployed position and is comprised between 10° and 60° when the stand is in the intermediate deployed position.

According to other advantageous characteristics of the invention, the stand in the retracted position is received in a completely integrated manner in a housing formed in a rear face of the casing, opposite the screen, so that the device can rest on a plane support or be easily put away in a compact and economical case.

According to yet other advantageous characteristics of the invention, the device comprises a structural part such as a metal crosspiece, fixed to the casing and on which the stand is mounted in a pivoting manner.

According to yet other advantageous characteristics of the invention, the structural part is constituted by a crosspiece a central part of which forms at least one stiffening angle on which the stand is mounted pivoting, and the ends of which are fixed to opposite edges of the casing, for example to the edges substantially adjacent to the long sides of the rectangular shape of the device. Said central part being able for example to be L-, T- or U-shaped. The L-shape forming an angle proves sufficiently rigid for small devices in practice and it offers the advantage of being inexpensive to produce by simply bending a piece of sheet metal.

According to yet other advantageous characteristics of the invention, the pin between the stand and the structural part is mounted tightly, so as to generate frictional forces intended to be overcome by the user when manually arranging the stand in the desired position, and not inadvertently under the simple weight of the device supported on the stand.

According to yet other advantageous characteristics of the invention, the free end of the stand which is opposite its axis of rotation forms a linear contact zone substantially parallel to the axis of rotation. The length of said contact zone is advantageously suited to the characteristics of the touch screen, in particular to its length, depending on the number as well as the positioning of the stand or stands according to the invention. For example in the case of two stands and/or of a touch screen with a small width for which a single stand is sufficient, a contact zone with a small length is sufficient for the device to be stable even when being supported in the corners opposite to those which are close to the support surface. In the case of a touch screen with a relatively large width when it is impossible to use two stands, provision is then made to use a stand with a foot offering linear contact with the support having a relatively great length. The stability of the assembly thus being substantially improved for all the support zones on the touch screen.

According to yet other advantageous characteristics of the invention, the maximum deployed position of the stand is delimited by a stop of this stand abutting against the casing and/or the structural part.

According to yet other advantageous characteristics of the invention, the intermediate deployed position of the stand is predetermined by a hard stop or means of indexing provided on the pin between the stand and the structural part.

According to yet other advantageous characteristics of the invention, the casing comprises a recess defining a zone for gripping the free end of the stand when it is situated in the retracted position.

According to yet other advantageous characteristics of the invention, the stand comprises at least two segments sliding longitudinally with respect to each other, in a telescopic manner.

According to yet other advantageous characteristics of the invention, the segments of the stand are retracted into each other so as to confer a minimum length on the stand when the device is arranged in its “reclining” position.

The invention will be better understood on reading the following description of a non-limitative embodiment of the invention and with reference to the attached drawings in which:

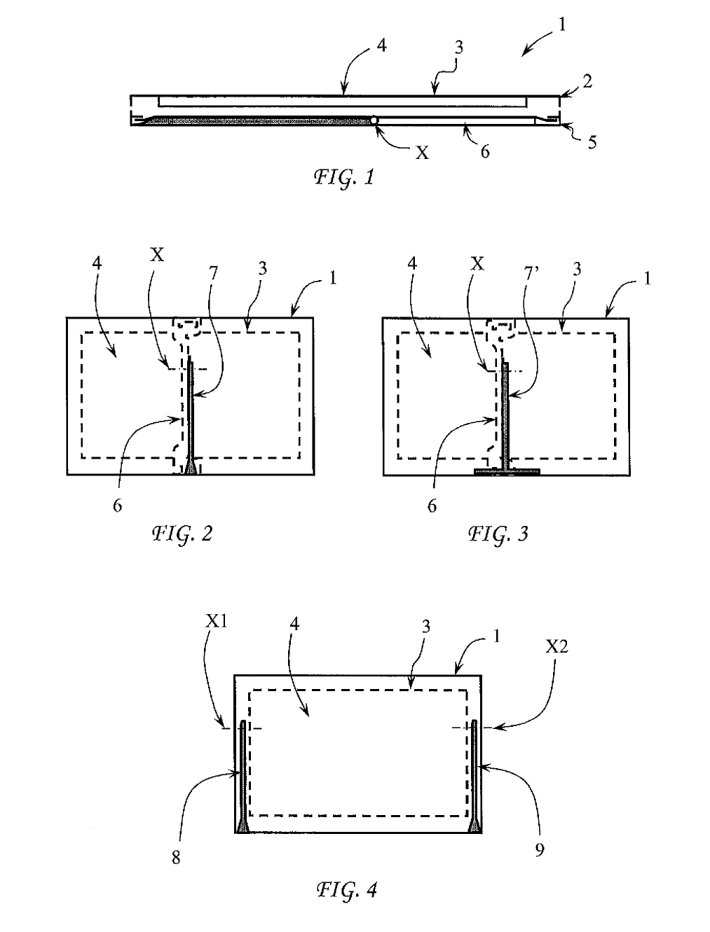

FIG. 1 shows a diagrammatic side view of a electronic device according to the invention, when flat,

FIG. 2 shows a view of the rear face of a first embodiment of the electronic device in FIG. 1, in which the device comprises a single central stand, this view corresponding to a bottom view of the device represented in FIG. 1,

FIG. 3 shows a view of the rear face of another embodiment of the electronic device according to the invention, in which the device also comprises a single central stand, the foot of which in this example offers a long linear contact zone substantially parallel to the axis of rotation in order to improve stability, this view corresponding to a bottom view of the device shown in FIG. 1,

FIG. 4 shows a view similar to that in FIGS. 2 and 3, of another embodiment of the invention, in which the device comprises two side stands,

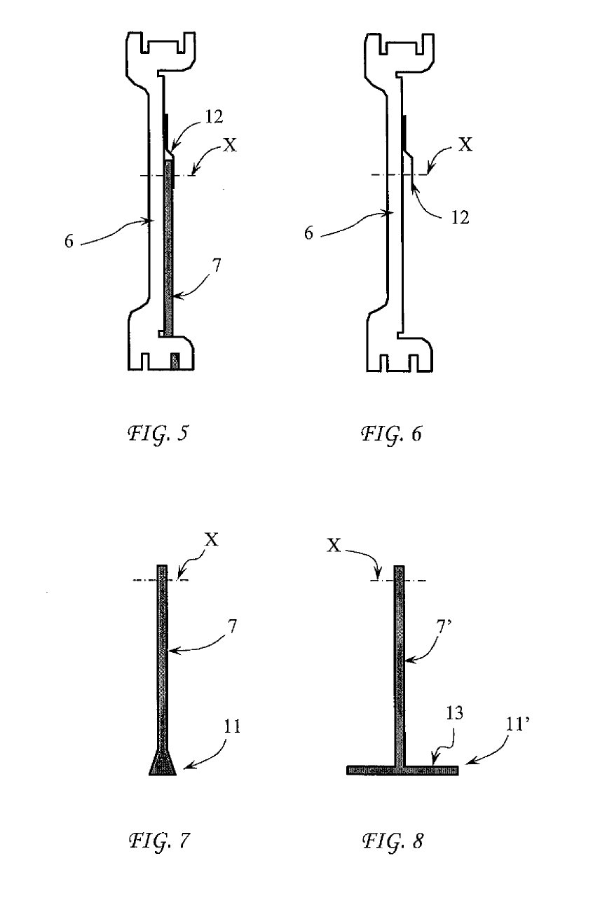

FIG. 5 shows a structural element provided in the casing of the device according to the invention, as well as the stand mounted on the latter,

FIG. 6 shows only the structural element in FIG. 5,

FIG. 7 shows only the stand in FIGS. 2 and 5,

FIG. 8 shows only the stand in FIG. 3,

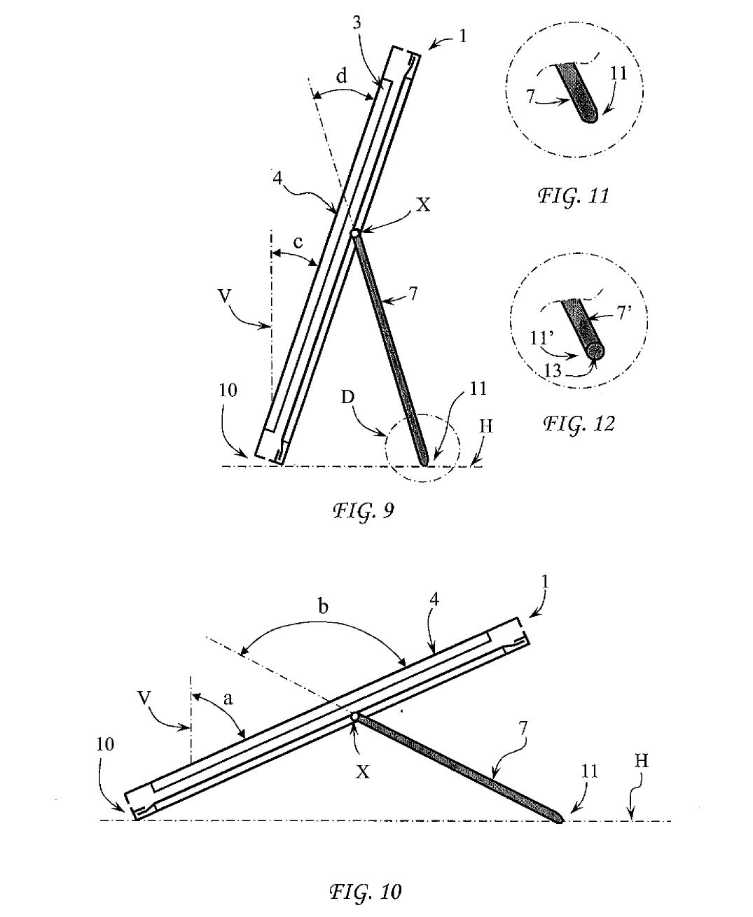

FIG. 9 shows the device according to the embodiment of the invention in FIGS. 1 and 2, placed on a plane support, in its “upright” position, the stand being in its maximum deployed position,

FIG. 10 shows the device according to the invention placed on a plane support, in its “reclining” position, the stand being in its intermediate deployed position,

FIG. 11 shows a detail of the embodiment of the stand in FIG. 9,

FIG. 12 shows a detail of another embodiment of the stand in FIG. 9,

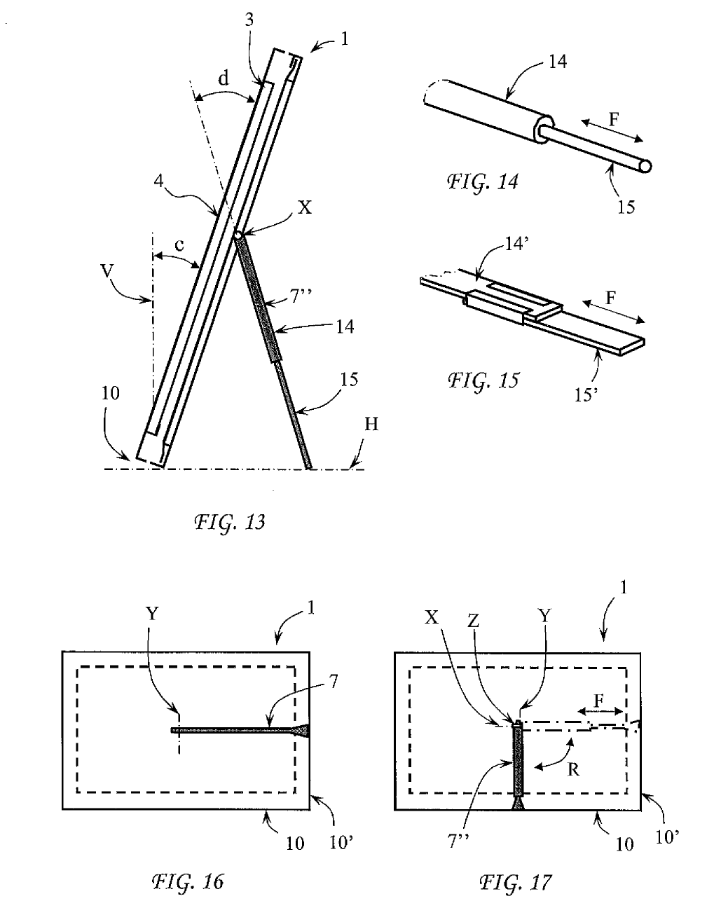

FIG. 13 shows another embodiment of the invention in which the stand is telescopic, the view being similar to that in FIG. 9,

FIGS. 14 and 15 illustrate two embodiment variants of a telescopic stand according to FIG. 13,

FIG. 16 illustrates another embodiment of the invention, in which the stand is arranged parallel to a long edge of the casing, and

FIG. 17 illustrates another embodiment of the invention, in which the stand is articulated with respect to the casing by a ball-socket joint.

FIG. 1 shows a diagrammatic side view of an electronic device with a touch screen according to the invention. The device is presented in the form of a one-piece tablet in which the screen is rigidly integral with the body of the device and perfectly incorporated in the latter. The device has a general flat outer shape which, seen from above (or flat) with respect to FIG. 1, is typically rectangular, as illustrated in FIGS. 2 to 4. The device comprises a casing 1 constituted by a front half-casing 2 on which the touch screen 3 is mounted, an outer visible face 4 of which is accessible through a window provided in the front half-casing 2. The casing 1 also comprises a rear half-casing 5 capable of being fixed to the front half-casing 2, opposite the outer visible face 4.

The casing 1 is made of plastic material. It comprises at least one inner structural part 6, situated in the space delimited by two half-casings 2, 5. The structural part 6 made of metallic material has a general elongated shape, a central part of which has an L-shaped cross-section, the structural part thus constituting an angle stiffening the casing. Its ends are fixed, for example by clipping, to the inner face of the rear half-casing 5, in a zone adjacent to sides of the rectangle formed by the casing, and substantially in the middle of these sides. In the example shown in FIGS. 1 and 2, the structural part is fixed to the long sides of the casing.

A description is given below of a particular embodiment of the invention, in which the device comprises a single retaining stand 7 situated substantially in the centre or in the middle of the casing (FIG. 2), this centre/middle being considered in the longitudinal direction of the casing, i.e. parallel to the long sides of its rectangular shape. In this embodiment, the stand 7 has a general elongated shape.

Of course, other embodiments can be envisaged without exceeding the scope of the invention; in particular, FIG. 3 shows an embodiment in which the device comprises a single stand 7′ also situated in the centre or in the middle of the casing, with respect to its longitudinal direction. In this embodiment, the stand 7′ has a general T-shape.

FIG. 4 also shows an example in which the device comprises two stands 8, 9 having general elongated shapes, arranged respectively close to two opposite edges of the casing, these edges corresponding to the short sides of the rectangular shape in the example shown.

A description is given below of an embodiment of the invention corresponding to FIGS. 1 and 2, it being understood that, unless otherwise indicated, the features and characteristics are also present in the other embodiments. The device comprises a stand 7 which is accessible via the rear face of the casing. The stand is either received in a housing provided in the rear face of the rear half-casing 5, or accessible via a passage provided in the rear half-casing 5. This stand is mobile between a folded-away or retracted position in the body of the device, and at least one deployed position in which it is used to support the casing. The stand 7 is pivoting with respect to the casing 1 about an axis of articulation X, between a retracted position in the casing 1 of the device, and a maximum deployed position, the maximum deployed position corresponding to a so-called “reclining” configuration of the device, illustrated in FIG. 10. In this position, the outer visible face 4 of the touch screen forms an angle a comprised between 50° and 85° with respect to the vertical direction V, when a base 10 of the device, corresponding in this example to one of the long sides of the rectangular casing, is supported on a horizontal plane H, and the free end 11 of the stand 7, opposite the axis of articulation X, is supported on the same horizontal plane H. In this example, it is noted that the axis of articulation X is parallel to the long sides of the casing. In this reclining configuration of the device, the angle b formed between the rectilinear direction of the stand 7 and the outer visible face 4 of the touch screen 3 is comprised between 100° and 175°.

The stand can also be arranged in at least one intermediate deployed position, illustrated in FIG. 9, which corresponds to a so-called “upright” configuration of the device. In this position, the outer visible face 4 of the touch screen 3 forms an angle c comprised between 5° and 45° with respect to the vertical direction V, when the base 10 of the device and the free end 11 of the stand are supported on the horizontal plane H.

With reference to FIGS. 5 and 6, the stand 7 is very advantageously mounted in a pivoting manner on the structural part 6 fixed to the casing 1, so as to be connected to a rigid element of the device, and capable of ensuring an appropriate distribution of force in the casing 1. The stand 7 is more precisely connected to the central angle part of the structural part 6. Said central part has an L-shaped cross-section in which one of the branches of the L extends perpendicular to the plane of the outer visible face 4 of the screen 3. The structural part 6 also comprises a lug 12 fixed to the abovementioned branch of the L, a free end of this lug, opposite its area of attachment, being separated from the branch of the L, so as to form a space capable of receiving one end of the stand, and to provide an axis of articulation X ensuring the connection of the stand to the casing 1 or the body of the device. In the example illustrated, the axis of articulation X is situated in a defined area between the middle and approximately 80% of the length of the structural part.

The connection is clamped between the stand 7 and the structural part 6, so as to generate frictional forces intended to immobilize the stand 7 with respect to the casing 1 in the absence of manipulation by the user. These frictional forces are intended to be overcome by the user in order to place the stand in the desired position. On the other hand, the frictional forces are suited to not moving the stand inadvertently, for example under the simple weight of the device supported on the stand 7.

The longitudinal part of the stand 7 is preferably made of steel, and its shape is orientated in order to offer maximum rigidity in the direction opposing the main forces. This part of the stand is advantageously produced by means of a simple blade cut from sheet steel. The blade thus formed being oriented so that its larger surface is perpendicular to the surface of the screen.

As shown by FIG. 11 illustrating the embodiment detail D in FIG. 9, the free end 11 of the stand 7 which is supported on the horizontal plane H is preferably linear and is presented in the form of a segment the length of which is approximately 5 to 10 mm, this segment being substantially parallel to the axis of articulation X. This free end 11 has a curved shape as illustrated by FIG. 11. The free end of the stand is preferably made of plastic material by overmoulding of the end of the metal longitudinal part. The free end of the stand being provided to produce a non-damaging and non-slip contact zone for the support surfaces and for ease of gripping so as to facilitate the deploying of the stand from the so-called retracted position. The maximum deployed position of the stand 7 (FIG. 10) is delimited by a stop (not shown) of the stand 7 abutting against a contact zone with the casing 1 or the structural part 6. Moreover, the intermediate deployed position of the stand 7 (FIG. 9) is predetermined by a hard stop or means of indexing (not shown) provided on the pin between the stand 7 and the structural part 6, conferring a stability on the stand and to aid the user in locating this position.

The casing 1 also comprises a recess (not shown) defining a gripping zone around the free end 11 of the stand 7 when it is in retracted position, making it easy to grasp this free end 11 in order to pivot the stand 7 about its axis.

Apart from the two deployed positions of the stand 7 which have been described above, the invention also includes the case where the stand comprises a third deployed position or even more positions.

Advantageously, the casing comprises a recess (not shown) in which the free end 11 of the stand forms a projection, so as to define for the user (including a user “without fingernails”) a zone for gripping the stand 7 when it is situated in retracted position. Alternatively, this recess can be replaced by an outer form of the casing vis-á-vis which the free end 11 of the stand forms a projection or protuberance intended to be easily gripped by the user in order to deploy the stand 7.

As already mentioned, the embodiment of the invention in FIGS. 3 and 12 relates to a stand 7′ having the general shape of a T, one transverse branch 13 of which is situated at the free end 11′ of the stand 7′, opposite the articulation about the axis X. This transverse branch or foot 13 forms an elongated and more precisely linear support zone distributing the forces and friction over the horizontal plane H, further improving the stability of the device and preventing any degradation of the surface on which this support plane is placed.

In another embodiment illustrated in FIGS. 13 to 15, the device according to the invention can be equipped with a pivoting stand 7″ also comprising two segments 14, 15 sliding longitudinally with respect to each other, in a telescopic manner. Thus the length of the stand 7″ can be finely adjusted in a manner suited to different configurations for supporting the device. In a variant which is not shown, the stand can comprise more than two sliding segments, for example three or four segments. The sliding joint between the segments is clamped or comprises friction means allowing the relative movement of the segments by a manual action of the user but is suited to preventing any inadvertent movement of the segments, in particular under the simple weight of the device which is supported on the stand 7″. According to an embodiment example illustrated in FIG. 14, the segments 14, 15 have a closed cross-section, for example circular, square, or equivalent. The segments are mounted concentrically and are retracted or deployed according to the arrow F corresponding to the longitudinal direction of the segments.

According to another embodiment variant illustrated in FIG. 15, the segments 14′, 15′ can have a non-closed cross-section, for example in the shape of an I or U or any other suitable shape. An embodiment example is illustrated in the form of bars sliding with respect to each other according to the arrow F also corresponding to the longitudinal direction of the segments.

In all cases, stop means (not shown) are provided in order to prevent the detaching of the segments and to guarantee that they remain in contact over a sufficient area of overlap, including in the maximum deployed position, so as not to alter the main function of the stand which is to allow firm and stable support of the device between the reclining position and the upright position. Moreover, means for reinforcing or indexing the elements with each other (for example of the pin-hole type) can be provided when the segments are in their maximum deployed position so as to increase resistance to the compression of the stand. These reinforcing or indexing means are self-locking when the segments are deployed and can also be self-unlocking above a threshold of compressive force applied to the stand.

In an embodiment having a telescopic stand, the segments 14; 15; 14′; 15′ of the stand 7″ are preferably retracted into each other so as to confer a minimum length on the stand when the device is arranged in its “reclining” position. The stand, which is then situated in a maximum deployed angular position with respect to the casing abuts against the casing of the device and offers further resistance to bending and compression in a compact or retracted configuration of its segments. In this position, the stand is thus more suited to resisting the forces applied by the user to the touch screen, this situation typically corresponding to the reclining position of the device.

With reference to FIG. 16 another embodiment is shown in which the stand 7 is one-piece and hinged with respect to the casing about an axis of articulation Y substantially parallel to the short sides of the rectangle formed by the casing 1. The stand 7 extends longitudinally parallel to the long sides of the casing 1. In this example, the base 10′ of the device on which it rests between reclining and upright positions is constituted by one of the short sides of the casing. Of course, the housing for receiving the stand 7 in folded-away or retracted position is oriented in the same way as the stand.

The device according to the invention can also comprise two stands (not shown), namely a first stand corresponding to the embodiment in FIG. 2 (stand parallel to a short side of the casing) and a second stand corresponding to the embodiment in FIG. 16 (stand parallel to a long side of the casing 1), so as to allow the two positions for placing the device on a support plane H: the base on which the device rests in both cases is respectively constituted by a long edge 10 of the casing or a short edge 10′ of the casing 1.

Of course, the housing for receiving each stand in the retracted position is oriented in the same way as the associated stand.

According to another embodiment of the invention, illustrated in FIG. 17, the device comprises a single stand 7″ connected to the casing by a ball-socket joint. The stand 7″ is thus hinged with respect to the casing about an axis Z perpendicular to the plane of the outer face 4 of the screen 3. This rotation according to the arrow R makes it possible to swing from a first configuration of use corresponding to FIG. 2 (stand parallel to the short sides of the casing 1, and capable of pivoting about an axis X parallel to the long sides of the casing 1) to a second configuration of use corresponding to FIG. 16 (stand parallel to the long sides of the casing 1, and capable of pivoting about an axis Y parallel to the short sides of the casing 1). The first configuration is shown by a solid line while the second configuration is shown by a dot-and-dash line. In this embodiment, it is advantageous to provide that the stand 7″ is constituted by telescopic segments 14, 15 in order to compensate for the differences in height between the hinge of the stand and each of the bases 10 or 10′, for identical given angles of tilt, as they have been defined with respect to the reclining position or the upright position of the device. It can be provided that the device comprises two housings for receiving the stand 7″ corresponding to each of the two configurations of use, the rotation about the axis Z taking place after detaching the stand from the casing 1, i.e. after pivoting the stand 7″ about the axis X or Y depending on the case. It can also be provided that the stand comprises only a single receiving housing. In this case the hinge of the stand is mobile in translation with respect to the casing 1 over a travel of the order of 1 to 3 mm, allowing the stand to be taken out of its housing before it can be pivoted about the axis of articulation X or Y.

Of course, the invention is not limited to the means which have just been described and includes all equivalent techniques.

For example, in other embodiment variants of the invention, the stand can be made of plastic material.

1. Electronic device with a touch screen (3), in particular of the one-piece type or capable of adopting a general one-piece form, comprising a casing (1) on which the touch screen (3) is mounted, the device having a general flattened shape delimited by two substantially parallel and rectangular opposite faces, one of which substantially incorporates the outer visible face (4) of the touch screen (3), characterized in that it comprises at least one stand (7-9; 7′; 7″) pivoting with respect to the casing (1) between a retracted position in the casing of the device (1), and a maximum deployed position, corresponding to a so-called “reclining” configuration of the device, in which the angle (a) between the outer visible face (4) of the touch screen (3) and the vertical (V) is comprised between 50° and 85° when a base (10) of the device and the stand (7-9; 7′; 7″) are supported on a horizontal plane (H), the stand (7-9; 7′; 7″) moreover being able to be arranged in at least one intermediate deployed position, corresponding to a so-called “upright” configuration of the device, in which the angle (c) between the outer visible face (4) of the touch screen (3) and the vertical (V) is comprised between 5° and 45° when the base (10) of the device and the stand (7-9; 7′; 7″) are supported on the horizontal plane (H).

2. Device according to claim 1, characterized in that the angle (b) formed between the rectilinear direction of the stand (7-9; 7′; 7″) and the outer visible face (4) of the touch screen (3) is comprised between 100° and 175° when the stand (7-9; 7′; 7″) is in the maximum deployed position and is comprised between 10° and 60° when the stand (7-9; 7′; 7″) is in the intermediate deployed position.

3. Device according to claim 1, characterized in that the stand (7-9; 7′; 7″) in the retracted position is received in a completely integrated manner in a housing formed in a rear face of the casing (1), opposite the screen (3), so that the device can rest on a plane support (H) or be put away in a case.

4. Device according to claim 1, characterized in that it comprises a structural part (6) such as a metal crosspiece, fixed to the casing (1) and on which the stand (7-9; 7′; 7″) is mounted in a pivoting manner.

5. Device according to claim 4, characterized in that the structural part (6) is constituted by a crosspiece a central part of which forms a stiffening angle on which the stand (7-9; 7′; 7″) is mounted pivoting, and the ends of which are fixed to opposite edges of the casing (1).

6. Device according to claim 4, characterized in that the pin between the stand (7-9; 7′; 7″) and the structural part (6) is mounted tightly, so as to generate frictional forces intended to be overcome by the user when manually arranging the stand (7-9; 7′; 7″) in the desired position, and not inadvertently under the simple weight of the device supported on the stand.

7. Device according to claim 1, characterized in that the free end (11) of the stand (7-9; 7′; 7″) which is opposite its axis of rotation (X) forms a linear contact zone substantially parallel to the axis of rotation (X).

8. Device according to claim 4, characterized in that the maximum deployed position of the stand (7-9; 7′; 7″) is delimited by a stop of this stand (7-9; 7′; 7″) abutting against the casing (1) and/or the structural part (6).

9. Device according to claim 4, characterized in that the intermediate deployed position of the stand (7-9; 7′; 7″) is predetermined by a hard stop or means of indexing provided on the pin between the stand (7-9; 7′; 7″) and the structural part (6).

10. Device according to claim 1, characterized in that the casing (1) comprises a recess defining a zone for gripping the free end of the stand (7-9; 7′; 7″) when it is situated in the retracted position.

11. Device according to claim 1, characterized in that the stand (7″) comprises at least two segments (14; 15; 14′; 15′) sliding longitudinally with respect to each other, in a telescopic manner.

12. Device according to claim 11, characterized in that the segments (14; 15; 14′; 15′) of the stand (7″) are retracted into each other so as to confer a minimum length on the stand when the device is arranged in its “reclining” position.

13. Device according to claim 2, characterized in that the stand (7-9; 7′; 7″) in the retracted position is received in a completely integrated manner in a housing formed in a rear face of the casing (1), opposite the screen (3), so that the device can rest on a plane support (H) or be put away in a case.

14. Device according to claim 2, characterized in that it comprises a structural part (6) such as a metal crosspiece, fixed to the casing (1) and on which the stand (7-9; 7′; 7″) is mounted in a pivoting manner.

15. Device according to claim 5, characterized in that the pin between the stand (7-9; 7′; 7″) and the structural part (6) is mounted tightly, so as to generate frictional forces intended to be overcome by the user when manually arranging the stand (7-9; 7′; 7″) in the desired position, and not inadvertently under the simple weight of the device supported on the stand.
